(19) United States
(12) Patent Application Publication
(10) Pub. No.: US 2025/0006623 A1
(43) Pub. Date: Jan. 2, 2025

(54) FORMING POROUS DIELECTRIC STRUCTURES WITH SPATIALLY-CONTROLLED POROSITY

(71) Applicant: Intel Corporation, Santa Clara, CA (US)

(72) Inventors: Shuqi Lai, Phoenix, AZ (US); Jieying Kong, Chandler, AZ (US); Dilan Seneviratne, Phoenix, AZ (US); Whitney Bryks, Tempe, AZ (US)

(73) Assignee: Intel Corporation, Santa Clara, CA (US)

(21) Appl. No.: 18/217,056

(22) Filed: Jun. 30, 2023

(51) Int. Cl. H01L 23/498

(52) U.S. Cl. CPC H01L 23/49894; H01L 23/49822; H01L 23/49838

(57) ABSTRACT

Microelectronic integrated circuit package structures include one or more integrated circuit (IC) package metallization levels comprising metallization features. A dielectric material is adjacent to one or more of the metallization features, where the dielectric material comprises a matrix material and a surfactant. A plurality of substantially spherical pores are within the matrix material, where the substantially spherical pores are surrounded by an outer shell comprising the matrix material.

### BACKGROUND

In electronics manufacturing, integrated circuit (IC) packaging is a stage of manufacture where an IC that has been fabricated on a die or chip comprising a semiconducting material is coupled to a supporting case or “package” that can protect the IC from physical damage and support electrical interconnect suitable for further connecting to a host component, such as a printed circuit board (PCB). In the IC industry, the process of fabricating a package is often referred to as packaging, or assembly.

As demand for high performance computing (HPC) continues to rise, integration of heterogeneous devices within an IC package has become an important performance driver. Uniform controllable dielectric constants of dielectric materials are needed to improve signal propagation for such packaged devices. Control of dielectric properties of materials within package structures can affect such parameters as routing signal loss and impedance mismatch. Surface treatment is often necessary to enhance a dielectric matrix-filler interaction, which can lead to bridging between the treated fillers and hence may increase the melt viscosity of corresponding build up materials; and the increased melt viscosity may lead to difficulty of vacuum lamination, compromising thickness uniformity and filling capability of laminated films. Size options for hollow fillers have limited availability, which may eventually restrict the minimum dielectric thickness that can be achieved.

### BRIEF DESCRIPTION OF THE DRAWINGS

The subject matter described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIGS. 1A-1B are cross-sectional views of IC package structures comprising die structures having scallop structures on bulk silicon die sidewalls, in accordance with some embodiments.

FIGS. 1C-1D are top views of IC package structures comprising porous dielectric structures, in accordance with some embodiments.

FIG. 1E is a cross-sectional view of an IC package structure comprising a porous dielectric structure, in accordance with some embodiments.

FIGS. 2A-2E illustrate cross-sectional views of structures formed during the fabrication of IC package structures comprising porous dielectric structures, in accordance with some embodiments.

FIGS. 3A-3C illustrate cross-sectional views of structures formed during the fabrication of IC package structures comprising porous dielectric structures, in accordance with some embodiments.

FIGS. 4A-4E illustrate cross-sectional views of structures formed during the fabrication of IC package structures comprising porous dielectric structures, in accordance with some embodiments.

FIGS. 5A-5B illustrate flow charts of processes for the fabrication of IC package structures having porous dielectric structures, in accordance with some embodiments.

FIG. 6 is a functional block diagram of an electronic computing device, in accordance with some embodiments of the present disclosure.

### DETAILED DESCRIPTION

Embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicate that two or more elements are in either direct or indirect (with other intervening elements between them) physical or electrical contact with each other, and/or that the two or more elements co-operate or interact with each other (e.g., as in a cause and effect relationship).

The terms “over,” “under,” “between,” and “on” as used herein refer to a relative position of one component or material with respect to other components or materials where such physical relationships are noteworthy. For example in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct physical contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the explicit context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent.

The term “package” generally refers to a self-contained carrier of one or more dice, where the dice are attached to the package substrate, and may be encapsulated for protection, with integrated or wire-bonded interconnects between the dice and leads, pins or bumps located on the external portions of the package substrate. The package may contain a single die, or multiple dice, providing a specific function. The package is usually mounted on a printed circuit board for interconnection with other packaged integrated circuits and discrete components, forming a larger circuit.

The term “dielectric” generally refers to any number of non-electrically conductive materials that make up the structure of a package substrate.

The term “metallization” generally refers to metal layers formed over and through the dielectric material of the package substrate. The metal layers are generally patterned to form metal structures such as traces and bond pads. The metallization of a package substrate may be confined to a single layer or in multiple layers separated by layers of dielectric.

The term “bond pad” generally refers to metallization structures that terminate integrated traces and vias in integrated circuit packages and dies. The term “solder pad” may be occasionally substituted for “bond pad” and carries the same meaning.

The term “solder bump” generally refers to a solder layer formed on a bond pad. The solder layer typically has a round shape, hence the term “solder bump”.

The term “substrate” generally refers to a planar platform comprising dielectric and metallization structures. The substrate mechanically supports and electrically couples one or more IC dies on a single platform, with encapsulation of the one or more IC dies by a moldable dielectric material. The substrate generally comprises solder bumps as bonding interconnects on both sides. One side of the substrate, generally referred to as the “die side”, comprises solder bumps for chip or die bonding. The opposite side of the substrate, generally referred to as the “land side”, comprises solder bumps for bonding the package to a printed circuit board.

The vertical orientation is in the z-direction and it is understood that recitations of “top”, “bottom”, “above” and “below” refer to relative positions in the z-dimension with the usual meaning. However, it is understood that embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

Views labeled “cross-sectional”, “profile” and “plan” correspond to orthogonal planes within a Cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure.

Embodiments discussed herein address problems associated with optimizing dielectric properties and processability of integrated circuit (IC) materials. For example, a filler material may be added to a dielectric material in order to achieve desired material properties for IC device requirements, such as to achieve a reduced the coefficient of thermal expansion (CTE) and/or to enhance a thermal conductivity of an organic build-up (BU) material. The use of fillers, such as silica fillers for example, may require surface treatment to enhance a matrix-filler interaction. However, optimization of the surface treatment is time-consuming and highly dependent on the resin systems of the dielectric material where the fillers are embedded. Inappropriate surface treatment can lead to bridging between the treated fillers and hence can compromise the yield and increase the viscosity of corresponding build up materials. With unoptimized surface treatment, reliability is also at risk due to potential delamination at the filler-matrix interface during manufacturing and testing of the IC package and under practical operation conditions.

The requirements of providing a material with spatially-varied dielectric properties cannot be met by the current hollow filler approach. The embodiments herein can provide such a material by adding a chemical blowing agent (CBA) and a surfactant to a dielectric material to create a curable formulation which, once cured, contains nano/micro-pores that are not interconnected. The presence of closed (i.e., not interconnected) pores improves dielectric properties and offsets the adverse impacts induced by hollow filler incorporation. By selective doping of CBAs or using localized heating techniques, a material with spatially-controlled porosity and dielectric properties can be produced. Thus, package structures fabricated as described in the embodiments herein achieve improved reliability.

Embodiments describe nano/micro-pores with strong interaction with the matrix, as the pores are formed in situ with the matrix as the shell, requiring no surface treatment. Besides, CBAs and surfactants are typically inexpensive. So, they are more cost-effective than using hollow fillers in the case of uniform porosity and dielectric properties. The pore size can be tuned by varying concentrations and types of CBAs and surfactants, resins, precure degrees, cure temperatures and times; and smaller sizes can be achieved than those of available hollow fillers. Materials with uniform or spatially-controlled porosity and dielectric properties can be yielded, the latter realized by selective doping of CBAs or using localized heating techniques

Package structures fabricated according to the assembly processes of the embodiments herein may include an assembly having one or more integrated circuit (IC) package metallization levels comprising metallization features. A dielectric material is adjacent to one more of the metallization features. The dielectric material comprises a matrix material, such as an epoxy and a benzocyclobutene, and a surfactant such as ethylene oxide-propylene oxide copolymers. A plurality of substantially spherical pores are within the matrix material, wherein the substantially spherical pores are surrounded by an outer shell comprising the matrix material. A die is coupled to a package substrate comprising the dielectric material. The die may comprise a processor die or a memory component, for example, or any other suitable microelectronic components. By forming the package structures having pores formed in situ with the matrix as the shell as described herein, no surface treatment of the pores is required thus increasing the yield of build up materials and the reliability and performance of devices incorporating the embodiments of the present disclosure.

The architecture described herein may be assembled and/or fabricated with one or more of the features or attributes provided in accordance with various embodiments. A number of different assembly and/or fabrication methods may be practiced for generating package structures having nano/micro-pores within a matrix requiring no surface treatment, according to one or more of the features or attributes described herein.

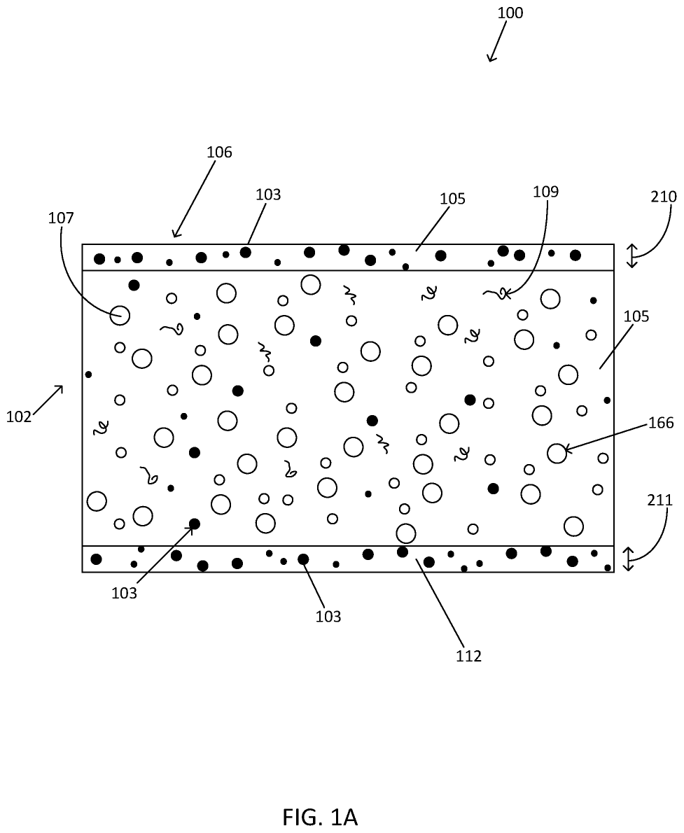

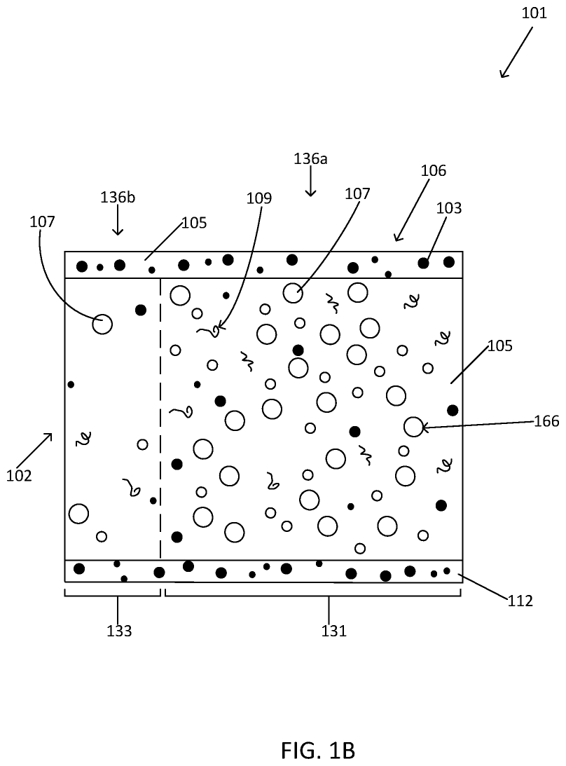

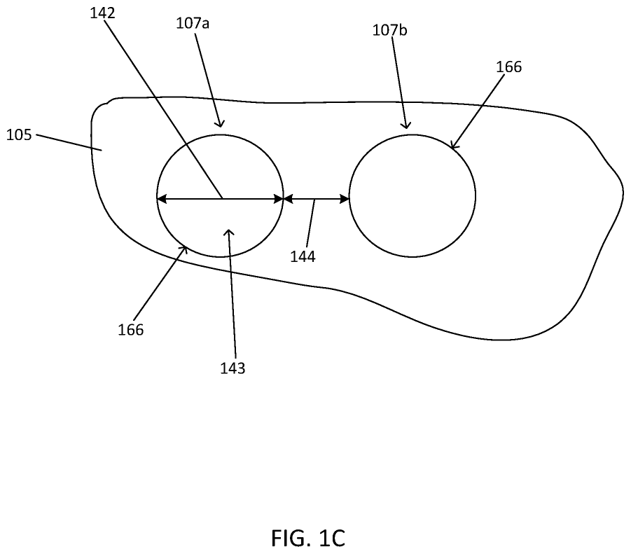

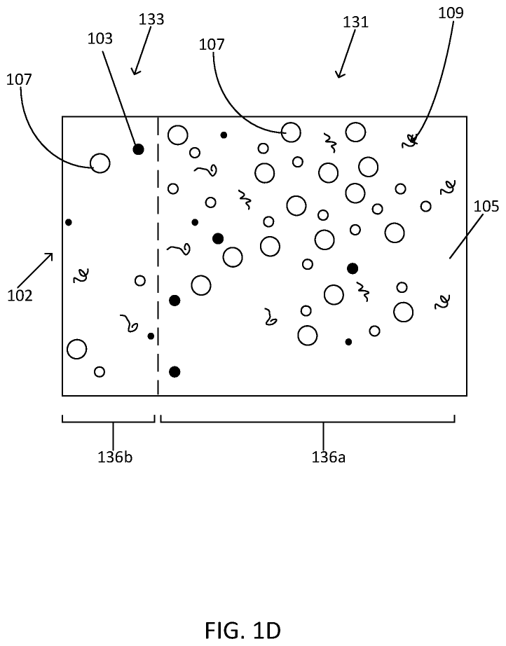

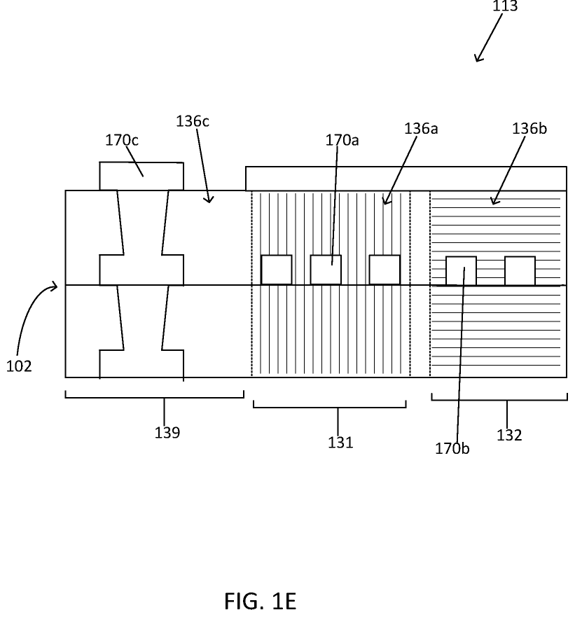

FIGS. 1A-1E illustrate embodiments of package structures including die structures. The package structures are formed utilizing incorporation of CBAs into a build up layer and thermally induced decomposition of CBAs. Spatially-controlled porosity can be achieved using local heating or spatial deposition. For example, the methods of fabrication described herein improve the properties of the IC dielectric materials of the embodiments.

FIG. 1A is a cross-sectional view of a portion of integrated circuit (IC) package structure 100, in accordance with some embodiments. In an embodiment, IC package structure 100 may comprise a multilayer dielectric material. In an embodiment, a first layer 102 may comprise a build up layer 102, wherein the build up layer may comprise a matrix material 105. In an embodiment, the matrix material 105 may comprise one or more of an epoxy or a benzocyclobutene, but may comprise any other suitable matrix materials on other embodiments. In an embodiment, the build up layer 102 may optionally comprise a filler 103 and may comprise a surfactant 109. The surfactant 109 may comprise ethylene oxide-propylene oxide copolymers, and the filler 103 may comprise one or more of silica, alumina, boron or nitrogen. In an embodiment, a percent composition of the surfactant within the build up layer 102 may comprise between about 1 percent by weight to about 30 percent by weight. In an embodiment, the percent composition of the filler 103 within the build up layer 102 may comprise between about 1 percent by weight to about 80 percent by weight.

In an embodiment, an optional second layer 106 layer may be on the first layer 102. In an embodiment, the second layer 106 may comprise a smooth surface which contains no surfactant 109. In an embodiment, the second layer 106 may comprise silicon nitride, titanium, copper, or a dielectric material such as the matrix material 105, but may comprise other suitable second layer 106 materials. A filler material 103 may be included within the second layer 106, which may comprise about 1 to about 80 percent weight composition. In an embodiment, a thickness 210 of the second layer 106 may comprise between about 0.5 microns to about 5 microns, in an embodiment.

An optional third layer 112 may be on a surface of the first layer 102, opposite the second layer 106. In an embodiment, the third layer 112 may comprise a layer resistant to moisture penetration, such as a barrier layer. Alternatively, the third layer 112 promotes adhesion to other materials within the package structure 100. The third layer 112 may comprise such materials as silicon nitride, plated copper or copper alloys, an adhesive layer, or other dielectric materials. The third layer 112 may encapsulate the package structure 100 and may provide a hermetic sealant layer. A filler material 103 may optionally be included in the third layer 112 which may comprise about 1 to about 80 percent weight composition within the third layer 112. In an embodiment, a thickness 211 of the third layer 112 may comprise between about 0.5 micron to about 1 micron, in an embodiment.

Nano/micro-pores 107 are within the build up layer 102, wherein the pores 107 comprise a diameter of about 1 nm to about 10 microns. The pores 107 may comprise a plurality of pores and are not interconnected with each other. The pores 107 improve dielectric properties of the build up layer 102 and offset adverse impacts (e.g., increased viscosity) induced by filler 103 incorporation. For example, the pores 107 may allow control over a dielectric constant value within the build up layer 102, since greater numbers of pores 107 will decrease the dielectric constant of the build up layer 102. In an embodiment, the concentration of pores 107 are substantially uniform throughout the build up layer 102. In an embodiment, the matrix material 105 is the outer core/shell 166 of the pore 107. There are no intervening layers between the pore 107 and the matrix shell 166. In an embodiment, the pore 107 comprises an air pore, i.e., filled with air.

FIG. 1B is a cross-sectional view of an IC package structure 101, in accordance with some embodiments. IC package structure 101 may comprise a multilayer dielectric material. In an embodiment, a first layer 102 may comprise a build up layer 102, wherein the build up layer 102 may comprise a matrix material 105. The matrix material 105 may comprise one or more of an epoxy or a benzocyclobutene. In an embodiment, the build up layer 102 may comprise a filler 103 and a surfactant 109. The surfactant 109 may comprise ethylene oxide-propylene oxide copolymers, and the filler 103 may comprise silica, alumina, boron or nitrogen. In an embodiment, the percent composition of the surfactant 109 within the build up layer 102 may comprise between about 1 percent by weight to about 30 percent by weight. In an embodiment, the percent composition of the filler 103 within the build up layer 102 may comprise between about 1 percent by weight to about 80 percent by weight.

In an embodiment, an optional second layer 106 layer may be on the first layer 102. In an embodiment, the second layer 106 may comprise a smooth surface which contains no surfactant 109 or CBA 108. In an embodiment, the second layer 106 may comprise silicon nitride, titanium, copper, or a dielectric material such as the matrix material 105. A filler material 103 may be included within the second layer 106, which may comprise about 1 to about 80 percent weight composition. An optional third layer 112 (similar to the third layer 112 of FIG. 1A) may be on a surface of the first layer 102, opposite the second layer 106.

Pores 107 are within the build up layer 102, wherein the pores 107 comprise a diameter of about 1 nm to about 10 microns. The pores 107 are not interconnected with each other. The pores 107 allow control over a dielectric constant value within the build up layer 102, since greater numbers of pores will decrease the dielectric constant of the build up layer 102. In an embodiment, a concentration of pores 107 are non-uniform throughout the build up layer 102. In an embodiment, the matrix material 105 is the outer core/shell 166 of the pores 107. There are no intervening layers between the pore 107 and the matrix shell 166. In an embodiment, the pore 107 comprises an air pore, i.e. filled with air. In an embodiment, a pore density 136 within a region of the bulk layer 102 may comprise the number of pores per unit area.

In an embodiment, a pore density 136a in a first region 131 of the bulk layer 102 may comprise above about twice a pore density 136b of a second region 133. In another embodiment, a pore density 136a of the first region 131 may comprise above about four times a pore density 136b of the second region 133. In another embodiment, a pore density 136a of the first region 131 may comprise above about half a pore density 136b of the second region 133. In an embodiment, the pore density 136 may vary in a lateral direction as viewed in a cross-sectional portion of the build up layer 102.

FIG. 1C depicts a top view of pores 107a, 107b within a matrix material 105. The pores 107a, 17b may comprise a distance 144 between each other in an embodiment and may comprise a substantially spherical shaped pore filled with a gas 143, such as air. In an embodiment, the distance 144 may be such that the pores are touching, but an outer shell 166 around the pores 107a, 107b are continuous, such that the pores 107a, 107b are closed. In some embodiments, the pores 107a, 107b may comprise a diameter 142, wherein the diameter may comprise about 1 nm to about 10 microns. In an embodiment, the pores 107 within the build up layer 102 of FIGS. 1A-B for example may comprise a plurality of pores 107 which may comprise a size distribution of within about 10 percent of the diameter 142.

FIG. 1D depicts a top view of pores 107 within a first portion 131 and a second portion 133 of a build up layer 102. The build up layer 102 may comprise a filler 103, a matrix material 105 and a surfactant 109. The first portion 131 comprises a first pore density 136a and the second portion 133 comprises a second pore density 136b. In an embodiment, a pore density 136 within a region of the bulk layer 102 may comprise a number of pores per unit area, such as per (please add metric of pore density).

FIG. 1E is a cross-sectional view of an IC package structure 113, in accordance with some embodiments. IC package structure 113 may comprise a build up layer 102 such as the build up layer 102 of FIG. 1B, for example. The build up layer 102 may comprise metal structures 170. The metal layers 170 may comprise portions of device structures, in an embodiment. The metal structures may comprise any suitable conductive metals and their alloys, such as copper, gold, silver, titanium, tungsten and their alloys, for example. The metal structures 170 may comprise portions of devices and/or routing conductive layers within a die/device. The build up layer 102 may comprise first region 131 comprising a first pore density 136a, a second region 132 comprising a second pore density 136b, and a third region 139 comprising a third pore density 136c. The pore densities 136a, 136b, 13c are not equal to each other in an embodiment. For example, the pore density 136a may be tailored to the device requirements of the metal/device layer 170a, the pore density 136b may be tailored to the device requirements of the metal layer 170b, and the pore density 136c may be tailored to the device requirements of the metal layer 170c. Because the pore density 136 is inversely proportional to the dielectric constant, device characteristics such as impedance mismatch and signal loss may be optimized by employing the methods and package structures described herein.

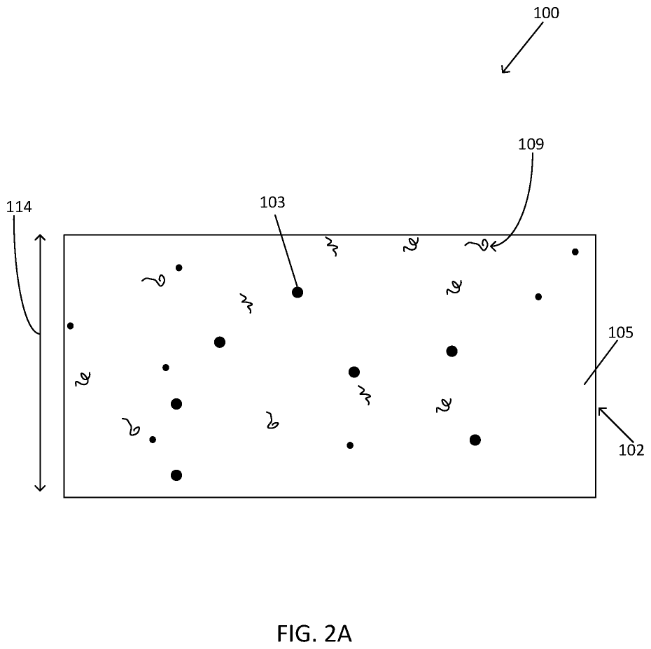

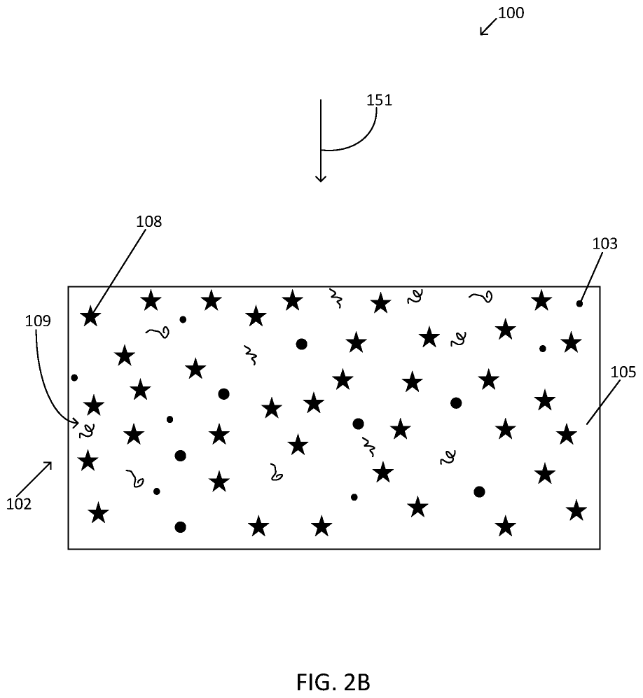

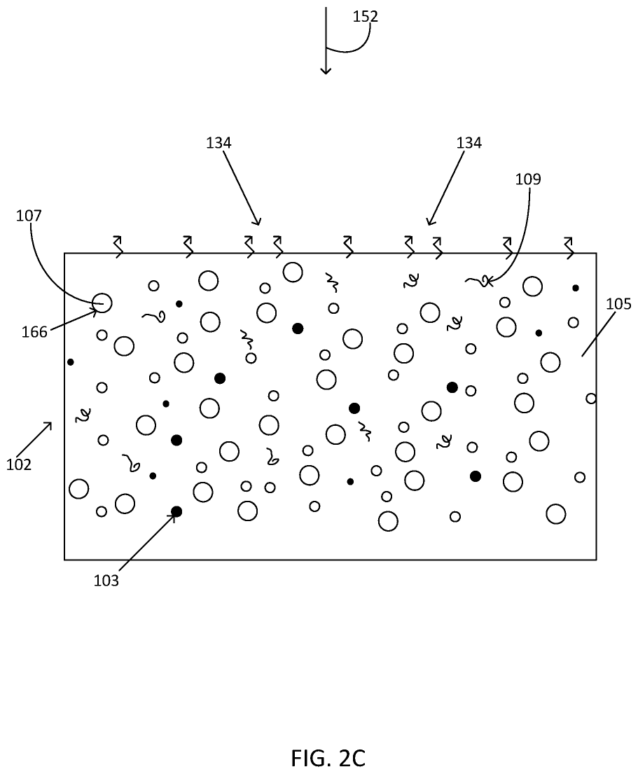

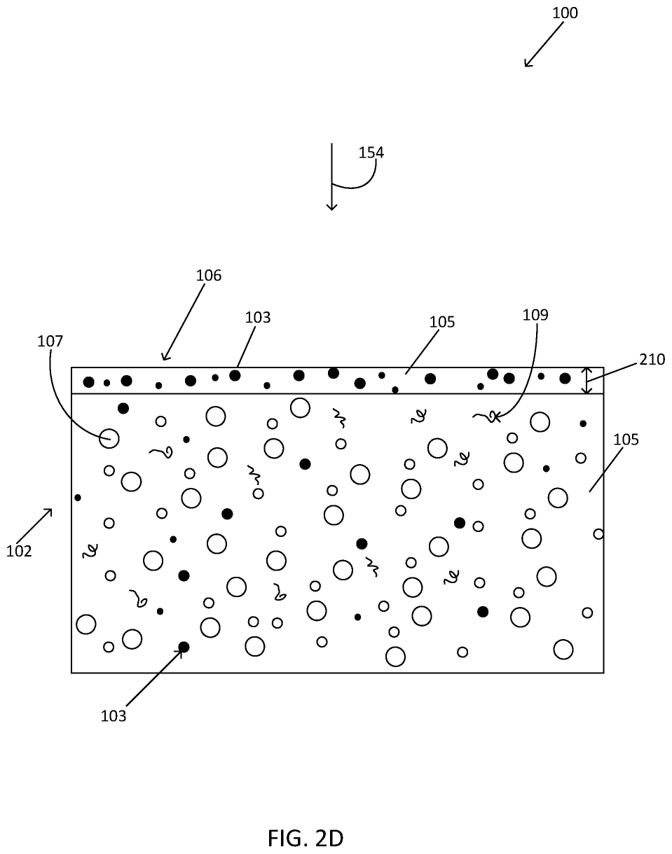

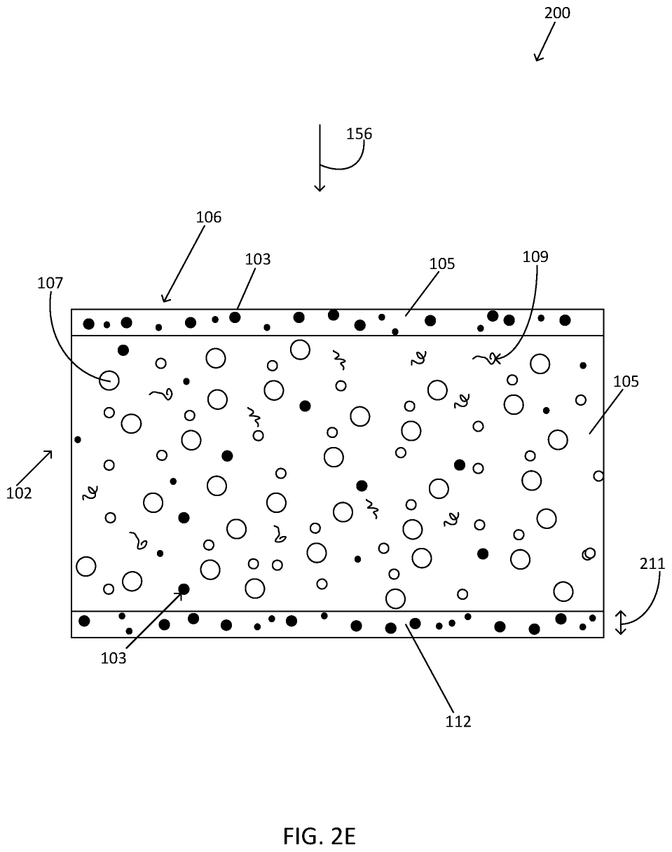

FIGS. 2A-2C illustrate embodiments of forming IC package structures (such as the IC package structures of FIGS. 1A-1D). FIG. 2A depicts a cross-sectional view of a portion of an IC package structure according to some embodiments. As shown, the IC package structure 100 may comprise a build up layer 102. In an embodiment, the build up layer 102 may comprise a matrix material 105 that may comprise one or more of an epoxy or a benzocyclobutene. In an embodiment, a thickness 114 of the build up layer 102 may be between about 10 to about 40 microns. In an embodiment, the build up layer 102 may optionally comprise a filler 103 and may comprise a surfactant 109. The surfactant 109 may comprise ethylene oxide-propylene oxide copolymers, and the filler 103 may comprise one or more of silica, alumina, boron nitrogen. In an embodiment, the percent composition of the surfactant within the build up layer 102 may comprise between about 1 percent by weight to about 30 percent by weight. In an embodiment, the percent composition of the filler within the build up layer 102 may comprise between about 1 percent by weight to about 80 percent by weight.

As depicted in FIG. 2B, a chemical blowing agent (CBA) 108 may be introduced into the build up layer 102 using any suitable addition process 151. In an embodiment, the CBA 108 may comprise ammonium bicarbonate or azodicarbonamide and may comprise a composition within the build up layer 102 of about 1 to about 50 percent by weight. The composition of the CBA 108 throughout the build up layer 102 may vary according to the particular application as will described in greater detail subsequently herein. In an embodiment, the surfactant 109 may be already present in the build up layer 102 as received during a manufacturing process. Likewise, the filler 103 may be already present in the build up layer 102 as received during a manufacturing process.

In an embodiment, the CBA 108 may be added to the build up layer 102 by mixing in a varnish used to manufacture dry dielectric films. Alternatively, a varnish can be directly used for coating the build up layer 102 by such methods as slit coating. In an embodiment, the addition process 151 may add the CBA 108 to the build up layer 102 in combination with the surfactant 109 and the filler 103. In an embodiment, the addition process 151 may add the CBA 108 in a uniform manner, wherein the concentration of the CBA 108 may be substantially the same throughout the build up layer.

In an embodiment, the build up layer 102 may be cured subsequent to the addition of the CBA 108 by utilizing a curing process 152 (FIG. 2C). In an embodiment, the curing process 152 may comprise placing the build up layer 102 in a vertical or a horizontal oven at a curing temperature. A curing temperature may comprise between about 100 and 250 degrees Celsius, in some embodiments, but will depend upon the particular materials. The cure time may vary as well. At an elevated temperature (preferably the cure temperature), the CBA 108 decomposes and releases gas 134. With the aid of the surfactant 109 that stabilizes gas bubbles, pores 107 are formed, wherein the pores 107 comprise a diameter of about 1 nm to about 10 microns. The pores 107 are not interconnected with each other. The pores 107 improve dielectric properties of the build up layer 102 and offset the adverse impacts (e.g., increased viscosity) induced by filler 103 incorporation. For example, the pores 107 may allow control over a dielectric constant value within the build up layer 102, since greater numbers of pores will decrease the dielectric constant of the build up layer 102. In an embodiment, the concentration of pores are substantially uniform throughout the build up layer 102.

No surface treatment is needed for strong matrix 105-filler 103 interaction, as the pores 107 are formed within the build up layer 102. The matrix material 105 comprises the shell 166 surrounding the pores 107. In an embodiment, the pores 107 are substantially spherical pores 107 and are surrounded by the outer shell 166 comprising the matrix material 105 with no intervening layers. The pore 107 size can be easily tuned by varying concentrations and types of CBAs 108, surfactants 109, resins, precure degrees, and cure temperatures and times, allowing for the formation of smaller pores 107 than non-in situ formed hollow fillers.

FIG. 2D depicts the formation 154 of an optional second layer 106 layer comprising a relatively smooth surface. The second layer may comprise a surface layer 106, which contains no surfactant or CBA in an embodiment. In an embodiment, the surface layer 106 may comprise a matrix material 105 and/or a filler 103. In an embodiment, the surface layer 106 may comprise silicon nitride, titanium, copper, or a dielectric material. The filler material 103 may comprise about 1 to about 80 percent weight composition within the surface layer 106. In an embodiment, a thickness 210 of the second layer 106 may comprise between about 0.5 microns to about 5 microns, in an embodiment.

FIG. 2E depicts the formation 156 of an optional third layer 112 layer comprising a moisture penetration layer 112. Alternatively, the optional third layer 112 may promote adhesion to other materials within the package structure 200, or it may prevent moisture penetration. The optional third layer 112 may be formed on top of another material such as silicon nitride, titanium, copper, an adhesive layer, dielectric materials, etc. to encapsulate the build up layer 102/package structure 200. A filler material 103 may be included which may comprise about 1 to about 80 percent weight composition within the third layer 112. In an embodiment, a thickness 211 of the third layer 112 may comprise between about 0.5 micron to about 1 micron, in an embodiment.

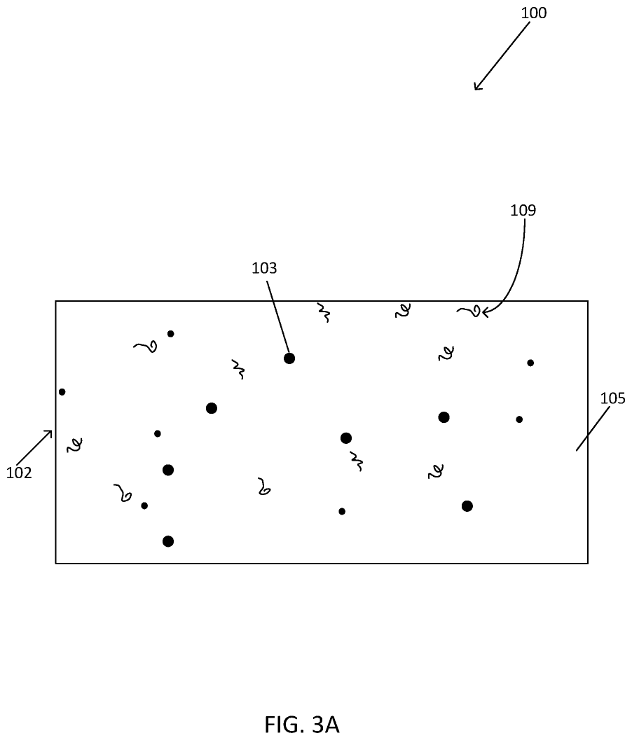

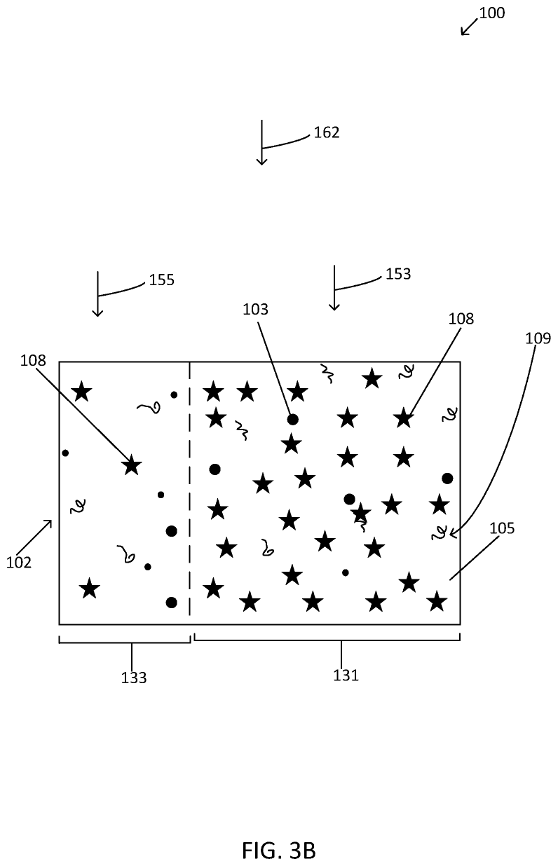

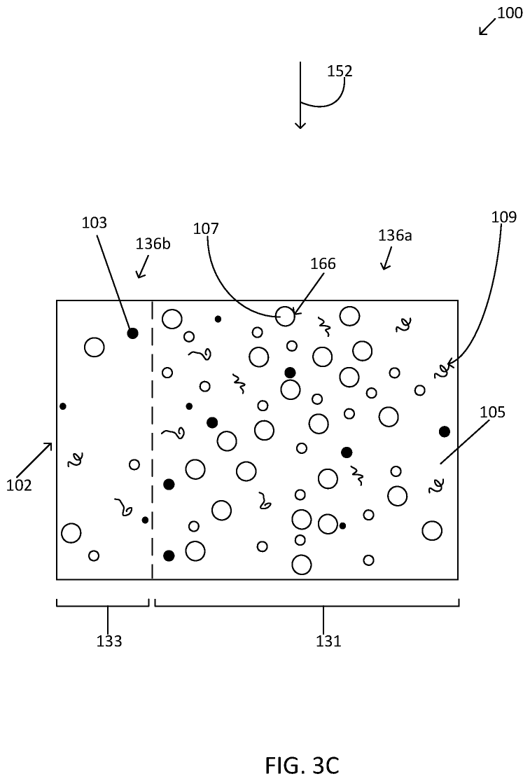

FIGS. 3A-3C depict another embodiment, wherein spatial dielectric constant control is enabled within a build up layer 102. As shown in FIG. 3A, the IC package structure 100 may comprise a build up layer 102. In an embodiment, the build up layer 102 may comprise a matrix material 105. The matrix material 105 may comprise one or more of an epoxy or a benzocyclobutene. In an embodiment, the build up layer 102 may optionally comprise a filler 103 and may comprise a surfactant 109. The surfactant 109 may comprise an ethylene oxide-propylene oxide copolymers, and the filler 103 may comprise one or more of silica, alumina, boron or nitrogen. In an embodiment, a percent composition of the surfactant 109 within the build up layer 102 may comprise between about 1 percent by weight to about 30 percent by weight. In an embodiment, a percent composition of the filler 103 within the build up layer 102 may comprise between about 0 percent by weight to about 80 percent by weight.

As depicted in FIG. 3B, a chemical blowing agent (CBA) 108 may be introduced into the build up layer 102 using an addition process 162. The CBA 108 may be introduced into the build up layer 102 by using any suitable addition process 162 such as by mixing in a varnish used to manufacture dry dielectric films. Alternatively, a varnish can be directly used for coating the build up layer 102 by such methods as slit coating. In an embodiment, the CBA 108 may comprise ammonium bicarbonate or azodicarbonamide and may comprise a composition within the build up layer 102 of about 1 to about 50 percent by weight. In an embodiment, the surfactant 109 may be already present in the build up layer 102 as received during a manufacturing process. Likewise, the filler 103 may already present in the build up layer 102 as received during a manufacturing process.

In an embodiment, the addition process 162 may add the CBA 108 to the build up layer 102 in combination with the surfactant 109 and the filler 103. In an embodiment, the addition process 162 may add the CBA 108 in a non-uniform manner, wherein a concentration of the CBA 108 may comprise a higher concentration in a first region 131 of the build up layer 102 than in a second region 133 of the build up layer 102. In other embodiments, different concentration regions of the CBA 108 may be placed in any area within the build up layer 102. In one embodiment, the CBA 108 can be added/doped in specific areas at different concentrations using methods such as inkjet printing, followed by a single or multiple step cure process.

For example, a first concentration 153 of CBA 108 may be added to the first region 131 of the build up layer 102, and a second concentration 155 may be added to a second region 133 of the build up layer 102. The build up layer 102 may be subsequently cured utilizing a curing process 152 in a vertical or horizontal oven (FIG. 3C). During the curing process 152 the CBA's 108 may be formed into pores 107, wherein the matrix material 105 is the outer core/shell 166 of each individual pore 107. There are no intervening layers between the individual pores 107 and the matrix shell 166. In an embodiment, individual pores 107 comprise an air pore, i.e. filled with air.

In an embodiment, a pore density 136 within a region of the bulk layer 102 may comprise a number of pores per unit area, such as per. In an embodiment, a pore density 136a in the first region 131 of the bulk layer 102 may comprise above about twice the pore density 136b of the second region 133. In another embodiment, a pore density 136a of the first region 131 may comprise above about four times a pore density 136b of the second region 133. In another embodiment, a pore density 136a of the first region 131 may comprise above about half a pore density 136b of the second region 133. In an embodiment, the pore density 136 may vary in a lateral direction as viewed in a cross-sectional portion of the build up layer 102. In an embodiment, the second portion 133 comprises a dielectric constant that is about 1.5 times greater than a dielectric constant of the first portion 131, since the number of pores is inversely related to the dielectric constant. By adding different concentrations of CBA's into different regions of the build up layer 102, spatial control of porosity and consequently the dielectric constant within the build up layer 102 may be achieved.

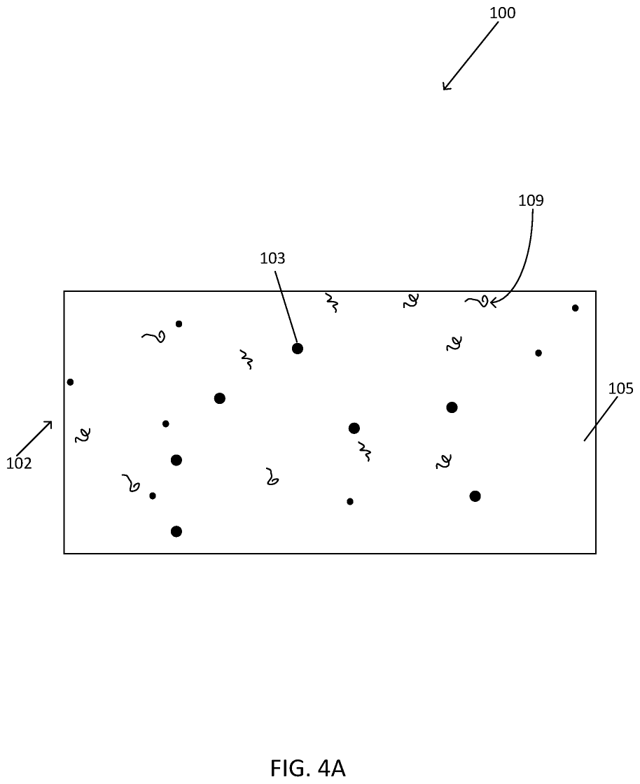

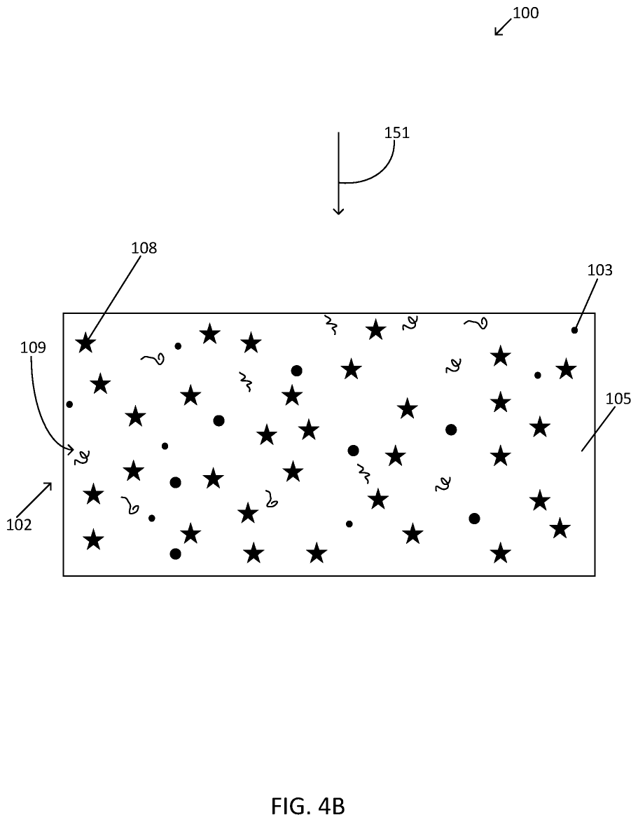

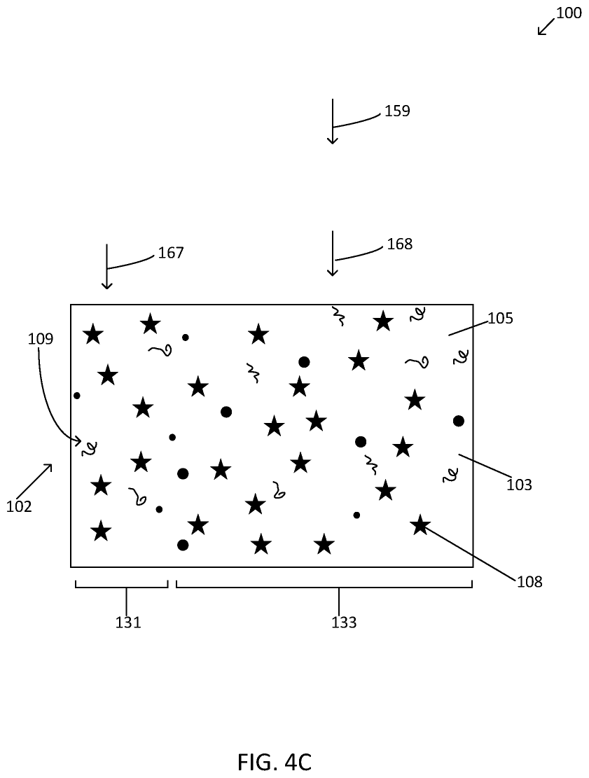

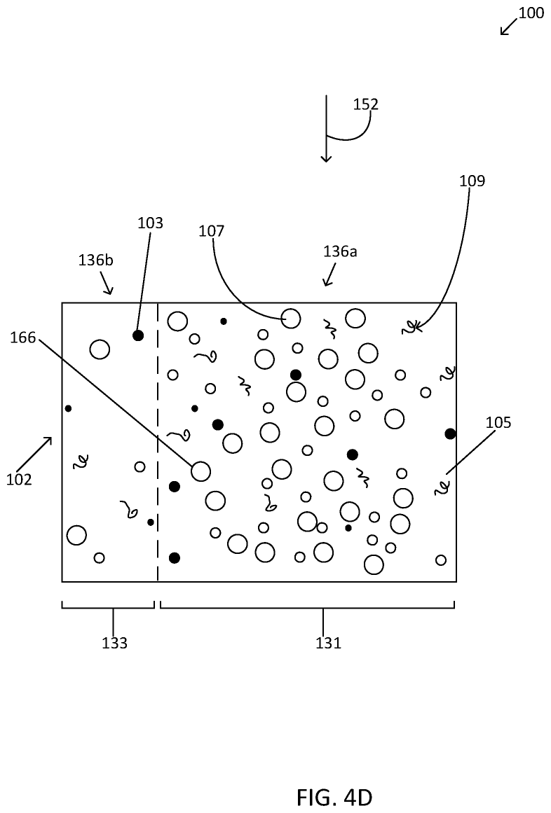

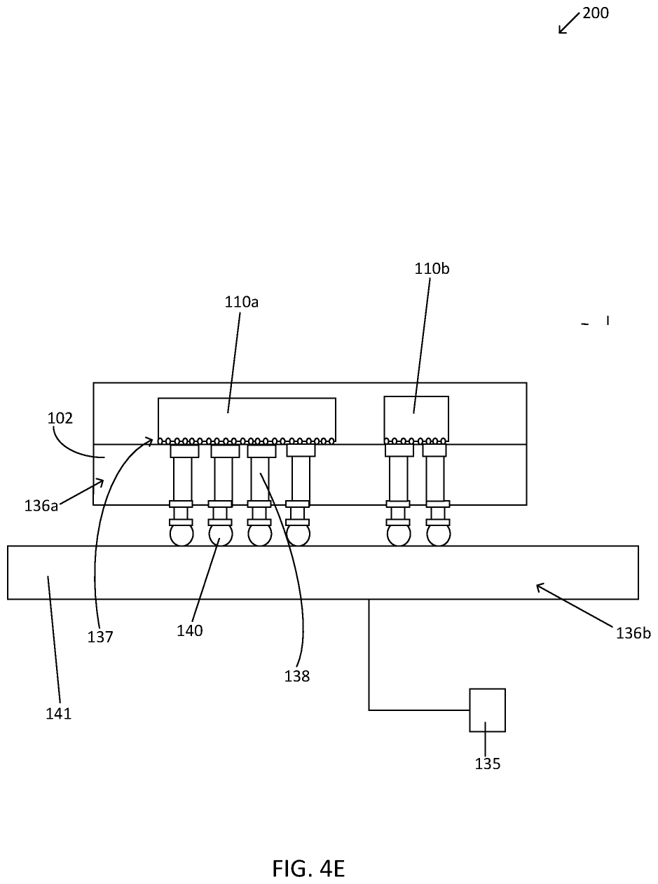

FIGS. 4A-4E depict an embodiment wherein a spatial variation in pore density is achieved by utilizing a localized curing process. FIG. 4A depicts a cross-sectional view of a portion of an IC package structure according to some embodiments. As shown, the IC package structure 100 may comprise a build up layer 102. In an embodiment, the build up layer 102 may comprise a matrix material 105. The matrix material 105 may comprise one or more of an epoxy or a benzocyclobutene. In an embodiment, the build up layer 102 may optionally comprise a filler 103 and may optionally comprise a surfactant 109. The surfactant 109 may comprise an ethylene oxide-propylene oxide copolymers, and the filler 103 may comprise one or more of silica, alumina, boron or nitrogen. In an embodiment, the percent composition of the surfactant 109 within the build up layer 102 may comprise between about 1 percent by weight to about 30 percent by weight and the percent composition of the filler 103 within the build up layer 102 may comprise between about 1 percent by weight to about 80 percent by weight.

As depicted in FIG. 4B, a chemical blowing agent (CBA) 108 may be introduced into the build up layer 102 using any suitable addition process 151. For example, the CBA 108 may be introduced into the build up layer 102 by mixing in a varnish used to manufacture dry dielectric films or applying a varnish and directly coating the build up layer 102 by such methods as slit coating. In an embodiment, the CBA 108 may comprise ammonium bicarbonate or azodicarbonamide and may be added 151 to the build up layer 102 to comprise a composition within the build up layer 102 of about 1 to about 50 percent by weight. In an embodiment, the surfactant 109 may be already present in the build up layer 102 as received during a manufacturing process. Likewise, the filler 103 may already present in the build up layer 102 as received during a manufacturing process.

In an embodiment, the CBA 108 may be added 151 to the build up layer 102 in a uniform manner, wherein the concentration of the CBA 108 may be substantially the same throughout the build up layer 102.

In an embodiment, the build up layer 102 may undergo a pre-curing process 159 in a vertical or horizontal oven (FIG. 4C). The pre-curing process 159 may comprise a localized heating process 159 in an embodiment, wherein a first regions 131 of the build up layer 102 may be heated at a first temperature 167, and a second region 133 of the build up layer 102 maybe heated at a second temperature 168. In an embodiment, the localized heating process 159 may utilize such heating tools as a nano-infrared (IR) tool or a continuous wave (CW) laser for example, to precure 159 different locations of the build up layer 102.

In an embodiment, the precure tools may be employed at different locations at different temperatures for different times. As a result, rheology of the matrix 105 can be spatially modulated, leading to spatially-controlled porosity in a subsequent cure step. In an embodiment, the size and density of pores 107 can be modulated by varying the pre-cure time and temperature. In an embodiment, a region of the build up layer 102 undergoing a long pre-cure time or a high pre-cure temperature may comprise a build up region with a higher viscosity than an adjacent region of the build up layer undergoing a short pre-cure time or a low pre-cure temperature.

Subsequent to the pre-curing process 159 the CBA's 108 in the build up layer 102 may undergo a cure process 152 wherein the CBA's may be formed into pores 107, wherein the matrix material 105 is the outer core/shell 166 of the pores 107 (FIG. 4D). There are no intervening layers between the individual pores 107 and the matrix shell 166 of the pores 107. In an embodiment, the pores 107 comprise an air pores, i.e. filled with air.

In an embodiment, a pore density 136a in a first region 131 of the bulk layer 102 may comprise above about twice a pore density 136b of a second region 133 of the bulk layer 102. In another embodiment, a pore density 136a of the first region 131 may comprise above about four times a pore density 136b of the second region 133. In another embodiment, a pore density 136a of the first region 131 may comprise above about half a pore density 136b of the second region 133. In an embodiment, the pore density 136 may vary in a lateral direction as viewed in a cross-sectional portion of the build up layer 102. In an embodiment, the second portion 133 comprises a dielectric constant that is about 1.5 times greater than a dielectric constant of the first portion 131, since the number of pores is inversely related to the dielectric constant. By utilizing localized heating within specific areas of the build up layer 102, spatial control of porosity and consequently the dielectric constant within the build up layer 102 may be achieved.

FIG. 4E depicts a package structure 200, wherein dice 110a, 110b are on a substrate 102, such as a package substrate 102. The dice 110a, 110b may comprise any suitable devices such as transistors, etc. The dice 110a, 110b may be conductively coupled to the package 102 by conductive structures 137. Dies 110a, 110b may comprise any suitable die/device including, but not limited to, a microprocessor, a chipset, a graphics device, a wireless device, a memory device, an application specific integrated circuit, a transceiver device, an input/output device, stacks thereof, or the like.

The conductive structures 137 may comprise any conductive element for coupling to an outside die or other device. In an embodiment, the conductive structures 137 may include one or more of silver, tin, or copper, or combinations or alloys thereof. The package substrate 102 may comprise a first pore density 136a similar to the build up layer 102 of FIG. 1A or 1B. Conductive vias 138 and solder balls 140 may couple the dice 110a, 110b to a board 141, such as a printed circuit board, for example. In an embodiment, the board 141 may comprise a dielectric material (similar to the build up layer 102 of FIG. 1A or 1B) which comprises a second pore density 136b. In an embodiment, one of the first pore density 136a or the second pore density 136b is greater than twice the other pore density. Conductive via structures 138 may comprise copper via structures in an embodiment. In some embodiments the conductive via structures 138 may comprise any suitable conductive material. In an embodiment, the conductive via structures 138 may comprise plated copper via structures 138. A power supply 135, which may comprise any suitable power supply as known in the art, may be coupled to dies 110a, 110b via IC package structure 200, in an embodiment.

Discussion now turns to operations for assembling and/or fabricating the discussed structures.

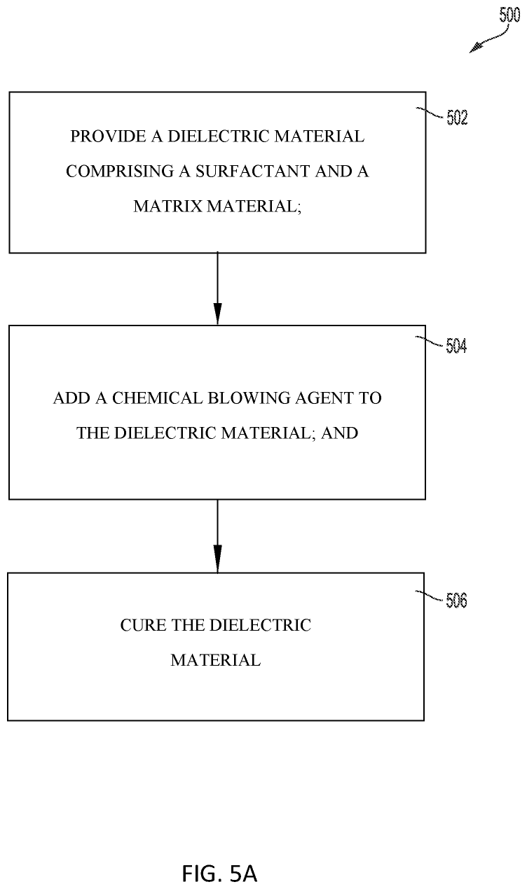

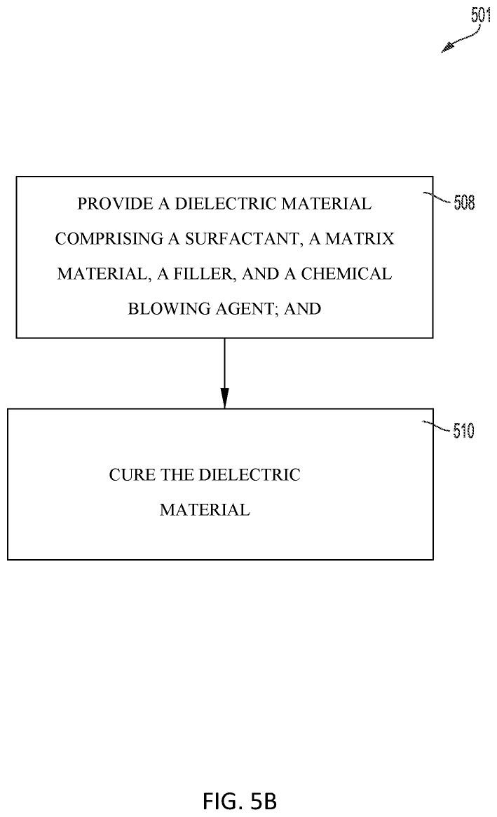

FIGS. 5A-5B depict flow charts of processes 500, 501 of fabricating microelectronic IC die structures according to some embodiments. For example, processes 500, 501 may be used to fabricate any of the microelectronic IC package structures of FIGS. 2A-2E, FIGS. 3A-3C, or FIGS. 4A-4E.

As set forth in block 502, a dielectric material may be provided comprising a surfactant and a matrix material (FIG. 5A, process 500). The matrix material may comprise one or more of an epoxy or a benzocyclobutene, and may comprise a thickness between about 10 to about 40 microns. In an embodiment, the matrix material may comprise a build up layer of a package substrate, for example. The dielectric material may optionally include a surfactant comprising an ethylene oxide-propylene oxide copolymers, and may optionally comprise a filler comprising one or more of silica, alumina, boron or nitrogen.

In an embodiment, a percent composition of the surfactant within the dielectric layer may comprise between about 1 percent by weight to about 30 percent by weight. In an embodiment, the percent composition of the filler within the dielectric layer may comprise between about 1 percent by weight to about 80 percent by weight. Any number of devices may be on and/or within the dielectric layer. The devices/dies may comprise any suitable die types such as a microprocessor, a chipset, a graphics device, a wireless device, a memory device, an application specific integrated circuit, a transceiver device, an input/output device, stacks thereof, or the like. In an embodiment the dielectric material may comprise one or more integrated circuit (IC) package metallization levels comprising metallization features adjacent to the dielectric material. The metal features may comprise portions of devices and/or routing conductive layers within a die/device.

As set forth in block 504, a chemical blowing agent (CBA) may be added to the dielectric material. In an embodiment, the surfactant may be added with the CBA. The CBA may be introduced into the dielectric layer by using any suitable addition process. In an embodiment, the CBA may comprise ammonium bicarbonate or azodicarbonamide and may comprise a composition within the dielectric layer of about 1 to about 50 percent by weight. In an embodiment, the surfactant may be added at the same time that the CBA is added to the dielectric layer or the surfactant may be already present in the dielectric layer as received during a manufacturing process. Likewise, the filler may be already present in the build up layer as received during a manufacturing process.

In an embodiment, the CBA may be added to the dielectric layer by mixing in a varnish used to manufacture dry dielectric films. Alternatively, a varnish can be directly used for coating the dielectric layer by such methods as slit coating. In an embodiment, the addition process may add the CBA in combination with the surfactant and the filler 103. In an embodiment, an addition process may add the CBA in a non-uniform or in a uniform manner within the dielectric layer. For example, the concentration of the CBA may be less concentrated in a first region than in a second region of the dielectric layer. In other embodiments, the high and low CBA concentration regions may be placed in any areas within the dielectric layer according to particular application needs. In one embodiment, the CBA can be added/doped in specific areas at different concentrations using methods such as inkjet printing, followed by a single or multiple step cure process. In an embodiment, adding the CBA comprises doping a first concentration of the CBA in a first region of the dielectric material and doping a second concentration of the CBA in a second region of the dielectric material, wherein the first concentration of the CBA is greater than 1.5 times the second concentration of the CBA.

As set forth in block 506, the dielectric material may be cured. In an embodiment, a pre-cure process may be employed prior to the cure process wherein a localized heating may be applied to the dielectric material in specific regions of the dielectric material. In an embodiment, the precure process results in the formation of regions within the dielectric material which comprise a higher pore density than other, adjacent regions within the dielectric material. The addition of different compositions of CBA's within adjacent regions of the dielectric material results in regions within the dielectric material which comprise different pore densities in the adjacent regions. The cure process causes the CBA's to decompose, releasing gases and forming air filled pores within the dielectric material. The temperatures and times for both the precure and cure processes may vary depending upon the particular application, but in an embodiment may comprise about 250 degrees Celsius about two hours.

In an embodiment, curing the dielectric material comprises forming a plurality of pores in the dielectric material, wherein an outer shell around individual pores of the plurality of pores comprises the matrix material. In an embodiment, curing the dielectric material comprises curing a first region of the dielectric material at a first temperature and curing a second region of the dielectric material at a second temperature, wherein the first temperature is greater than 1.5 times the second temperature. In an embodiment, a plurality of pores in the first region comprises a first pore density and a plurality of pores in the second region comprises a second pore density, wherein the first pore density is greater than 1.5 times the second pore density.

As set forth in block 508, a dielectric material may be provided comprising a surfactant, a matrix material, a filler and a CBA (process 501 of FIG. 5B). The matrix material may comprise one or more of an epoxy or a benzocyclobutene, and may comprise a thickness between about 10 to about 40 microns. In an embodiment, the matrix material may comprise a build up layer of a package substrate, for example. The dielectric material may optionally include a surfactant comprising an ethylene oxide-propylene oxide copolymers, and may optionally comprise a filler comprising one or more of silica, alumina, boron or nitrogen. In an embodiment, the CBA may comprise ammonium bicarbonate or azodicarbonamide and may comprise a composition within the dielectric layer of about 1 to about 50 percent by weight.

In an embodiment, a percent composition of the surfactant within the dielectric layer may comprise between about 1 percent by weight to about 30 percent by weight. In an embodiment, the percent composition of the filler within the dielectric layer may comprise between about 1 percent by weight to about 80 percent by weight. Any number of devices may be on and/or within the dielectric layer. In an embodiment, the CBA may be distributed within the dielectric material in a non-uniform or in a uniform manner. For example, the concentration of the CBA may be less concentrated in a first region than in a second region of the dielectric layer.

At block 510, the dielectric material may be cured. In an embodiment, a pre-cure process may optionally be employed prior to the cure process wherein a localized heating may be applied to the dielectric material in specific regions of the dielectric material. In an embodiment, the precure process results in the formation of regions within the dielectric material which comprise a higher pore density than other, adjacent regions within the dielectric material. In another embodiment, different concentrations of CBA's within adjacent regions of the dielectric material results in regions within the dielectric material which comprise different pore densities in the adjacent regions. The cure process causes the CBA's to decompose, releasing gases and forming air filled pores within the dielectric material. The temperatures and times for both the precure and cure processes may vary depending upon the particular application, but in an embodiment may comprise about 250 degrees Celsius about and about 2 hours.

The embodiments herein enable the formation of a plurality of pores comprising a uniform size but which are not merged with each other within the dielectric material. Having uniform, non-merged pores allows a greater control of the dielectric constant uniformity within the dielectric material. In some embodiments, the diameters of the plurality of pores are within about 10 percent or less of each other. Spatial control of the dielectric constant of the dielectric material is realized since the pore density can be selected for various regions as may be advantageous for various device dielectric constant requirements, for example. The embodiments enable the formation of a matrix shell around pores and enable spatial variation of porosity and thus spatial variation of the dielectric constant.

The presence of closed (i.e., not interconnected) pores improves dielectric properties and offsets adverse impacts induced by filler incorporation. By selective doping CBAs or using localized heating techniques, a material with spatially-controlled porosity and dielectric properties can be realized. Unlike hollow fillers, no surface treatment of nano/micro-pores is needed for strong interaction with the matrix material, as the pores are formed in situ with the matrix as the shell. CBAs and surfactant materials are typically inexpensive, so that the embodiments herein reduce the cost associated with the use of filler materials. The pore size can be easily tuned by varying concentrations and types of CBAs and surfactants, resins, precure degrees, cure temperatures and times. Smaller pore sizes can be achieved by utilizing the methods of the present disclosure. Materials with uniform or spatially-controlled porosity and dielectric properties can be yielded, the spatially controlled porosity achieved by selective doping of CBAs or using localized heating techniques.

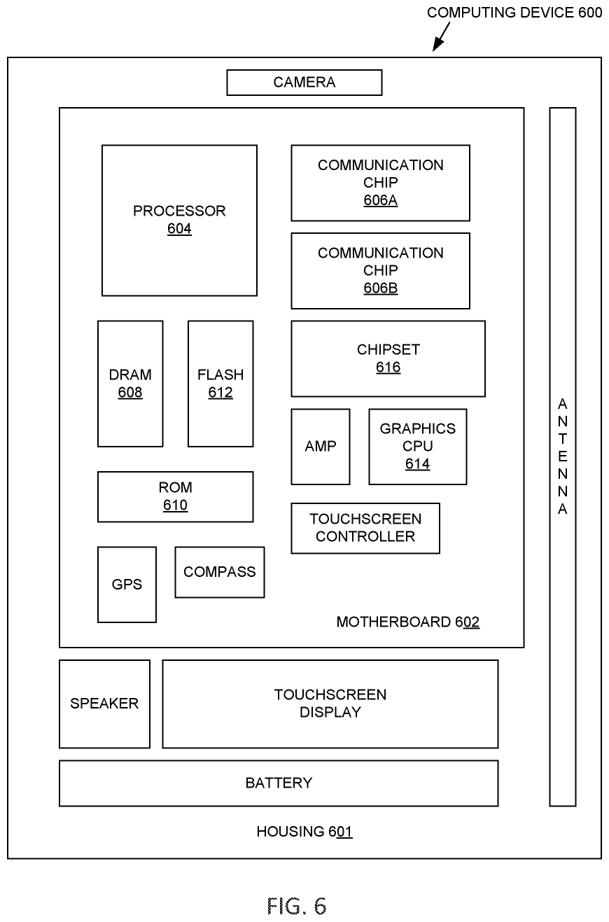

FIG. 6 illustrates an electronic or computing device 600 in accordance with one or more implementations of the present description. The computing device 600 may include a housing 601 having a board 602 disposed therein. The computing device 600 may include a number of integrated circuit components, including but not limited to a processor 604, at least one communication chip 606A, 606B, volatile memory 608 (e.g., DRAM), non-volatile memory 610 (e.g., ROM), flash memory 612, a graphics processor or CPU 614, a digital signal processor (not shown), a crypto processor (not shown), a chipset 616, an antenna, a display (touchscreen display), a touchscreen controller, a battery, an audio codec (not shown), a video codec (not shown), a power amplifier (AMP), a global positioning system (GPS) device, a compass, an accelerometer (not shown), a gyroscope (not shown), a speaker, a camera, and a mass storage device (not shown) (such as hard disk drive, compact disk (CD), digital versatile disk (DVD), and so forth). Any of the integrated circuit components may be physically and electrically coupled to the board 602. In some implementations, at least one of the integrated circuit components may be a part of the processor 604.

The communication chip enables wireless communications for the transfer of data to and from the computing device. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device may include a plurality of communication chips. For instance, a first communication chip may be dedicated to shorter range wireless communications such as Wi-Fi and Bluetooth and a second communication chip may be dedicated to longer range wireless communications such as GPS, EDGE, GPRS, CDMA, WiMAX, LTE, Ev-DO, and others.

The term “processor” may refer to any device or portion of a device that processes electronic data from registers and/or memory to transform that electronic data into other electronic data that may be stored in registers and/or memory. At least one of the integrated circuit components may include a device having one or more integrated circuit (IC) package metallization levels comprising metallization features. A dielectric material adjacent to one or more of the metallization features, comprises a matrix material and a surfactant. And plurality of substantially spherical pores are within the matrix material, wherein the substantially spherical pores are surrounded by an outer shell comprising the matrix material.

In various implementations, the computing device may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In further implementations, the computing device may be any other electronic device that processes data.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure. It is understood that the subject matter of the present description is not necessarily limited to specific applications illustrated in FIGS. 1-4. The subject matter may be applied to other integrated circuit devices and assembly applications, as well as any appropriate electronic application, as will be understood to those skilled in the art.

The following examples pertain to further embodiments and specifics in the examples may be used anywhere in one or more embodiments, wherein a first example is an apparatus comprising: one or more integrated circuit (IC) package metallization levels comprising metallization features; a dielectric material adjacent to one more of the metallization features, the dielectric material comprising a matrix material and a surfactant; and a plurality of substantially spherical pores within the matrix material, wherein the substantially spherical pores are surrounded by an outer shell comprising the matrix material.

In second examples, the first example further comprises wherein a first portion of the dielectric material comprises a first pore density and a second portion of the dielectric material comprises a second pore density.

In third examples, the second example further comprises wherein the first pore density is not less than twice the second pore density.

In fourth examples, the third example further comprises wherein the second portion comprises a dielectric constant that is not less than 1.5 times greater than a dielectric constant of the first portion.

In fifth examples, the first example further comprises wherein a diameter of an individual spherical pore of the plurality of substantially spherical pores comprises between 1 nm to 10 microns.

In sixth examples, the first example further comprises wherein a first layer is on a first surface of the dielectric material, wherein the first layer comprises the matrix material and is free of the surfactant, and wherein a thickness of the first layer is between 0.5 microns to 5 microns.

In seventh examples, the sixth example further comprises wherein a second layer is on a second surface of the dielectric material, opposite the first surface, wherein the second layer comprises one or more of silicon, nitrogen, copper, oxygen, aluminum, or boron.

In eighth examples, the seventh example further comprises wherein the dielectric material comprises between 1 to 30 percent by weight of the surfactant and the first layer comprises less than 0.2 percent by weight of the surfactant, and wherein the second layer comprises less than 0.2 percent by weight of the surfactant.

In ninth examples, the first example further comprises wherein the apparatus comprises a build-up layer of a microelectronic package structure, wherein a first metallization feature of the metallization features is within a first region of the build-up layer, the first region comprising a first pore density, and wherein a second metallization feature of the metallization features is within a second region of the build-up layer, the second region comprising a second pore density, wherein the first pore density is not less than 1.5 times greater than the second pore density.

In tenth examples, the first example further comprises wherein the matrix material comprises one or more of an epoxy material or a benzenecyclobutene, and wherein the surfactant comprises ethylene oxide-propylene oxide copolymers.

In eleventh examples, the first example further comprises wherein the dielectric material comprises a chemical blowing agent (CBA), wherein the CBA comprises one or more of ammonium bicarbonate or azodicarbonamide.

A twelfth example is a system, comprising: a substrate; a dielectric material on the substrate, the dielectric material comprising a matrix material and a surfactant; a plurality of pores within the dielectric material, wherein an outer shell surrounding individual ones of the plurality of pores comprises the matrix material, wherein: a first region of the dielectric material comprising a first pore density, and a second region of the dielectric material, adjacent to the first region, comprises a second pore density not less than 1.5 times the first pore density; and a device over the substrate.

In thirteenth examples, the twelfth example further comprises wherein a power supply is coupled to the device, and wherein the dielectric material comprises a portion of a build-up layer.

In fourteenth examples, the twelfth example further comprises wherein the dielectric material is between a first conductive trace and a second conductive trace.

In fifteenth examples, the twelfth example further comprises wherein a surface layer is on the dielectric material and on a portion of the device, and wherein the surface layer is free of the surfactant.

In sixteenth examples, the fifteenth example further comprises wherein a passivation layer is on a surface of the substrate, opposite the surface layer, wherein the passivation layer comprises one or more of silicon, oxygen or nitrogen, and wherein one or more conductive bump structures are adjacent the passivation layer.

A seventeenth example is an assembly, comprising: a dielectric material comprising a plurality of pores, wherein individual pores of the plurality of pores comprise a pore diameter between 1 nm and 10 microns; a first region and a second region of the dielectric material, wherein the first region comprises a first pore density and the second region comprises a second pore density, wherein the first pore density is greater than two times the second pore density; and a device over the dielectric material.

In eighteenth examples, the seventeenth example further comprises wherein one or more integrated circuit (IC) package metallization levels comprising metallization features are adjacent the dielectric material.

In nineteenth examples, the eighteenth example further comprises wherein the first region comprises a first dielectric constant and the second region comprises a second dielectric constant, wherein the second dielectric constant is at least ten percent greater than the first dielectric constant.

In twentieth examples, the eighteenth example further comprises wherein the apparatus comprises a build-up layer of a microelectronic package structure.

It will be recognized that principles of the disclosure are not limited to the embodiments so described but can be practiced with modification and alteration without departing from the scope of the appended claims. The above embodiments may include undertaking only a subset of such features, undertaking a different order of such features, undertaking a different combination of such features, and/or undertaking additional features than those features explicitly listed. The scope of the embodiments should, therefore, be determined with reference to the appended claims, along with the full scope of equivalents to which such claims are entitled.

What is claimed is:

1. An apparatus comprising:
one or more integrated circuit (IC) package metallization levels comprising metallization features;
a dielectric material adjacent to one more of the metallization features, the dielectric material comprising a matrix material and a surfactant; and
a plurality of substantially spherical pores within the matrix material, wherein the substantially spherical pores are surrounded by an outer shell comprising the matrix material.

2. The apparatus of claim 1, wherein a first portion of the dielectric material comprises a first pore density and a second portion of the dielectric material comprises a second pore density.

3. The apparatus of claim 2, wherein the first pore density is not less than twice the second pore density.

4. The apparatus of claim 3, wherein the second portion comprises a dielectric constant that is not less than 1.5 times greater than a dielectric constant of the first portion.

5. The apparatus of claim 1, wherein a diameter of an individual spherical pore of the plurality of substantially spherical pores comprises between 1 nm to 10 microns.

6. The apparatus of claim 1, wherein a first layer is on a first surface of the dielectric material, wherein the first layer comprises the matrix material and is free of the surfactant, and wherein a thickness of the first layer is between 0.5 microns to 5 microns.

7. The apparatus of claim 6, wherein a second layer is on a second surface of the dielectric material, opposite the first surface, wherein the second layer comprises one or more of silicon, nitrogen, copper, oxygen, aluminum, or boron.

8. The apparatus of claim 7, wherein the dielectric material comprises between 1 to 30 percent by weight of the surfactant and the first layer comprises less than 0.2 percent by weight of the surfactant, and wherein the second layer comprises less than 0.2 percent by weight of the surfactant.

9. The apparatus of claim 1, wherein the apparatus comprises a build-up layer of a microelectronic package structure, wherein a first metallization feature of the metallization features is within a first region of the build-up layer, the first region comprising a first pore density, and wherein a second metallization feature of the metallization features is within a second region of the build-up layer, the second region comprising a second pore density, wherein the first pore density is not less than 1.5 times greater than the second pore density.

10. The apparatus of claim 1, wherein the matrix material comprises one or more of an epoxy material or a benzenecyclobutene, and wherein the surfactant comprises ethylene oxide-propylene oxide copolymers.

11. The apparatus of claim 1, wherein the dielectric material comprises a chemical blowing agent (CBA), wherein the CBA comprises one or more of ammonium bicarbonate or azodicarbonamide.

12. A system, comprising:
a substrate;
a dielectric material on the substrate, the dielectric material comprising a matrix material and a surfactant;
a plurality of pores within the dielectric material, wherein an outer shell surrounding individual ones of the plurality of pores comprises the matrix material, wherein:
a first region of the dielectric material comprising a first pore density, and
a second region of the dielectric material, adjacent to the first region, comprises a second pore density not less than 1.5 times the first pore density; and
a device over the substrate.

13. The system of claim 12, wherein a power supply is coupled to the device, and wherein the dielectric material comprises a portion of a build-up layer.

14. The system of claim 12, wherein the dielectric material is between a first conductive trace and a second conductive trace.

15. The system of claim 12, wherein a surface layer is on the dielectric material and on a portion of the device, and wherein the surface layer is free of the surfactant.

16. The system of claim 15, wherein a passivation layer is on a surface of the substrate, opposite the surface layer, wherein the passivation layer comprises one or more of silicon, oxygen or nitrogen, and wherein one or more conductive bump structures are adjacent the passivation layer.

17. An assembly, comprising:
a dielectric material comprising a plurality of pores, wherein individual pores of the plurality of pores comprise a pore diameter between 1 nm and 10 microns;
a first region and a second region of the dielectric material, wherein the first region comprises a first pore density and the second region comprises a second pore density, wherein the first pore density is greater than two times the second pore density; and
a device over the dielectric material.

18. The assembly of claim 17, wherein one or more integrated circuit (IC) package metallization levels comprising metallization features are adjacent the dielectric material.

19. The assembly of claim 18, wherein the first region comprises a first dielectric constant and the second region comprises a second dielectric constant, wherein the wherein the second dielectric constant is at least ten percent greater than the first dielectric constant.

20. The assembly of claim 18, wherein the apparatus comprises a build-up layer of a microelectronic package structure.
